(19) United States
(12) Patent Application Publication
(10) Pub. No.: US 2021/0043442 A1
(43) Pub. Date: Feb. 11, 2021

(54) METHOD FOR IMPROVING FLATNESS OF SEMICONDUCTOR THIN FILM

(71) Applicant: Zing Semiconductor Corporation, Shanghai (CN)

(72) Inventors: Chenhua Dong, Shanghai (CN); Chihhsin Lin, Shanghai (CN); Gongbai Cao, Shanghai (CN)

(21) Appl. No.: 16/928,577

(22) Filed: Jul. 14, 2020

(30) Foreign Application Priority Data
Aug. 9, 2019 (CN) 201910734324.0

(51) Int. Cl. H01L 21/02

(52) U.S. Cl. CPC H01L 21/0262; H01L 21/02598; H01L 21/02532

(57) ABSTRACT

The present invention provides a method for improving semiconductor thin film flatness, the method comprises providing a wafer; performing a vapor phase deposition to from an epitaxial layer on the wafer; wherein a gas suppresses epitaxial layer growth is added during the vapor phase deposition in order to tune the thickness of the epitaxial layer on the wafer edge to improve flatness of the epitaxial layer. The vapor phase deposition of the present invention can improve the flatness of the epitaxial layer on the wafer edge by adding gases which suppress epitaxial layer growth to tune the thickness of the epitaxial layer on the wafer edge, therefore, the topography of the wafer is improved as well as the SFQR values are decreased.

### CROSS-REFERENCE TO RELATED APPLICATIONS

This application claims priority to P.R.C. Patent Application No. 20191734324.0 titled “a method for improving flatness of semiconductor thin film” filed on Aug. 9, 2019, with the State Intellectual Property Office of the People's Republic of China (SIPO).

### TECHNICAL FIELD

The present disclosure relates to semiconductor technology, and particularly, to a method for improving flatness of semiconductor thin film.

### BACKGROUND

In the field of semiconductor element manufacturing, a chemical vapor deposition (CVD) method is usually used to form a single-crystal silicon thin film on the wafer as an epitaxial layer, in order to improve the control of the crystal quality and conductivity of the wafer surface. Furthermore, it is used for manufacturing high-performance semiconductor elements. The flatness of the epitaxial layer is an important parameter affecting the performance of semiconductor devices. The better the flatness, the higher the yield and performance of the device. Therefore, the improvement of flatness is an important content of epitaxial wafer research. As the diameter of the silicon wafer increases, the improvement of the flatness of the epitaxial layer surface is not only an optimization of the quality, but also a reduction of the overall cost.

Therefore, it is necessary to propose a method for improving the flatness of a semiconductor thin film, which can effectively improve the flatness of the surface of the epitaxial layer and improve the yield and performance of the semiconductor device.

### SUMMARY

A series of simplified forms of concepts are introduced in the Summary of the Invention section, which will be described in further detail in the Detailed Description section. The summary of the invention is not intended to limit the key features and essential technical features of the claimed invention, and is not intended to limit the scope of protection of the claimed embodiments.

An objective of the present invention is to provide a method for improving flatness of semiconductor thin film, the method comprises the steps of:

providing a wafer; and

performing a vapor phase deposition process to grow an epitaxial layer on the wafer;

wherein a gas suppressing the growth of the epitaxial layer is employed during the vapor phase deposition process to tune the thickness of the epitaxial layer located at the edge region of the wafer and improve the flatness of the epitaxial layer.

In accordance with some embodiments, the vapor phase deposition process comprises chemical vapor deposition process.

In accordance with some embodiments, the vapor phase deposition process comprise a primary airflow and an edge secondary airflow.

In accordance with some embodiments, the epitaxial layer comprises a central region and an edge region, the main airflow is set to control the thickness of the epitaxial layer in the center region of the wafer, and the edge secondary airflow is set to control the thickness of the epitaxial layer at the edge region of the wafer.

In accordance with some embodiments, the edge secondary airflow comprises the gas suppressing the growth of the epitaxial layer.

In accordance with some embodiments, the gas suppressing the growth of the epitaxial layer comprises HCl.

In accordance with some embodiments, the vapor phase deposition process further comprises a deposition gas, the deposition gas comprises trichlorosilane; and the vapor phase deposition process further comprises a carrier gas, the carrier gas comprises H₂.

In accordance with some embodiments, the trichlorosilane flow rate is in a range of 1500˜2000 sccm, the H₂ flow rate is in a range of 1000˜1500 sccm, and the HCl flow rate is in a range of 0˜300 sccm.

In accordance with some embodiments, the epitaxial layer comprises single crystal silicon.

In accordance with some embodiments, an angle between the direction of the primary airflow and the direction of the edge secondary airflow is 70 °-110°.

### BRIEF DESCRIPTION OF THE DRAWINGS

Exemplary embodiments will be more readily understood from the following detailed description when read in conjunction with the appended drawings, in which:

FIG. 1 shows a graph of a wafer surface thickness according to the prior art.

FIG. 2 is a graph showing the thickness of the epitaxial layer formed by different H₂ flow rates.

FIG. 3 is a graph showing the thickness of the epitaxial layer formed by different TCS flow rates.

FIG. 4 is a schematic diagram of a method implementation according to an exemplary embodiment of the present invention.

FIG. 5 is a graph showing the thickness of the epitaxial layer formed by different HCl flow rates.

FIG. 6 is a schematic flowchart of a method for improving flatness of a semiconductor thin film according to an exemplary embodiment of the present invention.

### DETAILED DESCRIPTION

The embodiments of the present invention are described below by way of specific examples, and those skilled in the art can readily understand other advantages and effects of the present invention from the disclosure of the present disclosure. The present invention may be embodied or applied in various other specific embodiments, and various modifications and changes can be made without departing from the spirit and scope of the invention.

It should be understood that the present invention can be implemented in different forms and should not be construed as being limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity. The same reference numerals denote the same elements throughout.

It should be understood that when an element or layer is referred to as being “on”, “adjacent”, “connected to” or “coupled to” another element or layer, it can be directly on Other elements or layers are on, adjacent to, connected to, or coupled to other elements or layers, or intervening elements or layers may be present. In contrast, when an element is referred to as being “directly on”, “directly adjacent to”, “directly connected to” or “directly coupled to” another element or layer, there are no intervening elements or Floor. It should be understood that, although the terms first, second, third, etc. may be used to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below can be represented as a second element, component, region, layer or section without departing from the teachings of the present invention.

Spatial relation terms such as “below”, “above”, “on top of” etc. may be used herein for convenience of description to describe the relationship between one element or feature shown in the figure and other elements or features. It should be understood that in addition to the orientation shown in the figures, the spatial relationship terminology is intended to include different orientations of the device in use and operation. For example, if the device in the figures is turned over, then the element or feature described as “below” or “beneath” or “beneath” other elements or features would then be oriented “above” the other element or feature. Thus, the exemplary terms “below” and “below” can include both an orientation of above and below. The device may be otherwise oriented (rotated 90 degrees or otherwise) and the spatial descriptors used herein interpreted accordingly.

The terminology used herein is for the purpose of describing particular embodiments only and is not intended as a limitation of the invention. As used herein, the singular forms “a”, “an” and “the” are intended to include the plural forms as well, unless the context clearly indicates otherwise. It should also be understood that the terms “comprising” and/or “including”, when used in this specification, determine the presence of stated features, integers, steps, operations, elements and/or components, but do not exclude one or more other The presence or addition of features, integers, steps, operations, elements, parts, and/or groups. As used herein, the term “and/or” includes any and all combinations of the associated listed items.

In order to thoroughly understand the present invention, a detailed structure will be proposed in the following description in order to explain the technical solution proposed by the present invention. The preferred embodiments of the present invention are described in detail below. However, in addition to these detailed descriptions, the present invention may have other embodiments.

The local flatness of a wafer is generally evaluated using SFQR (Site Front Quotient Range) parameters. Specifically, the wafer is divided into several local sites. As an example, a 12-inch wafer or a wafer with a diameter of 300 mm is usually selected as a local area site. A wafer is divided into 324 local area sites, and each local area site corresponds to an SFQR value. In each local area Site, a reference line is made based on the thickness value, and the difference between the highest point, the lowest point in the local area site and the reference line is calculated, and then the maximum value of all local area sites reflects the flatness situation of the entire wafer.

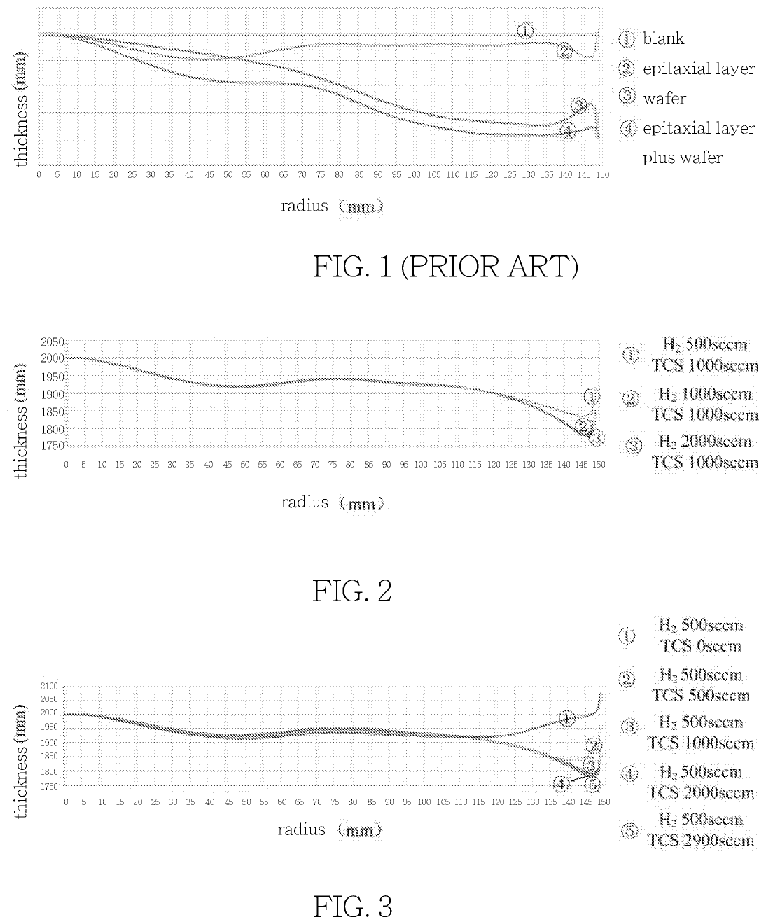

Due to the design of the epitaxial pedestal, the epitaxial layer will form a protrusion at the edge (145 mm) of the wafer, as shown by curve \textcircled{2} in FIG. 1. Further, because the wafer before epitaxy layer growth needs to undergo grinding, polishing, cleaning and other processing and forming processes, the processing of etching solutions such as polishing liquid can easily gathered at the edges (145 mm-148 mm), causing edge sinking, as shown in the curve \textcircled{3} of FIG. 1. The curve \textcircled{4} in FIG. 1 shows the effect of the superposition of the epitaxial layer protrusion and the wafer depression. When the epitaxial layer protrusion and the wafer depression are located at the same position, the SFQR value is small and the flatness of the epitaxial wafer produced will pass the inspection standard; when the epitaxial layer bump and the wafer recess are located at different positions, the SFQR value is large, and the flatness of the produced epitaxial wafer will be unqualified.

In view of the above problems, the present invention provides a method for improving the flatness of a semiconductor thin film. The specific embodiments of the method for improving the flatness of the semiconductor thin film of the present invention are described in details below.

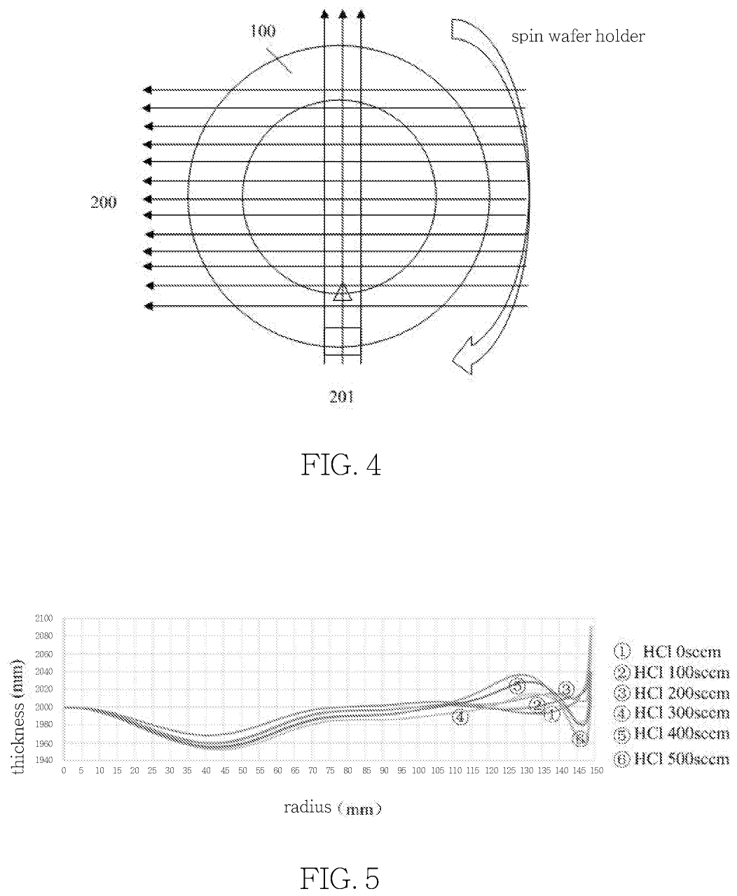

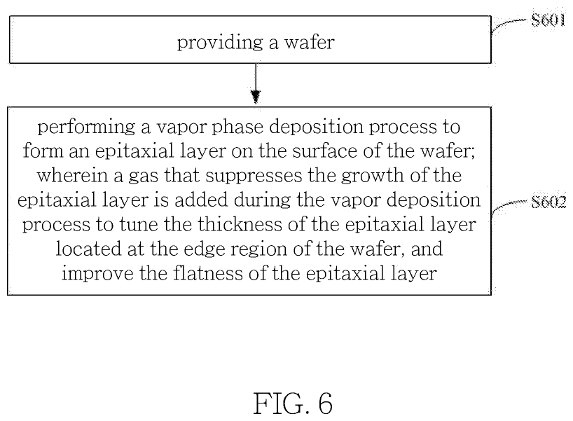

Please refer to FIG. 4 and FIG. 6, first, step S601 is performed to provide a wafer 100.

Exemplarily, in the present invention, the wafer 100 may be at least one of the following materials: single crystal silicon, silicon on insulator (SOI), silicon on insulator (SSOI), insulator Laminated silicon germanium (S—SiGeOI), silicon germanium on insulator (SiGeOI), and germanium on insulator (GeOI). As an example, the constituent material of the wafer 100 is monocrystalline silicon.

Exemplarily, the wafer 100 is pre-processed. The pretreatment includes grinding, polishing, cleaning, and other processes on the wafer 100. Specifically, first, the ingot is cut into wafers, and then processed by a polishing or grinding method so that each surfaces of the wafers are parallel, but the grinding process causes a lot of mechanical damage to the wafer surface and may increase the wafer warpage. In order to remove the damage, the wafer is immersed in a chemical solution used to etch the surface damage. Chemical mechanical polishing (CMP) technology was typically employed to trim a wafer to a predetermined thickness and polishes the wafer to achieve the required flatness and roughness specifications.

After the above pre-processing step, the local flatness of the surface of the wafer 100 is shown as curve \textcircled{3} in FIG. 1. The chemical solution easily accumulates at the edge of the wafer, causing the edge to sag.

Next, step S602 is performed: performing vapor deposition to form an epitaxial layer on the surface of the wafer 100; wherein a gas which suppresses the growth of the epitaxial layer is added during the vapor deposition process in order to tune the thickness of the epitaxial layer located at the edge region of the wafer, and improve the flatness of the epitaxial layer.

As shown in FIG. 4, the vapor deposition comprises a primary airflow 200 and an edge secondary airflow 201. The primary airflow 200 is set to control the thickness of the epitaxial layer at the center area of the wafer, and the edge secondary airflow 201 is set to control the thickness of the epitaxial layer at the edge area of the wafer. Further, an angle between the direction of the primary airflow 200 and the direction of the edge secondary airflow 201 is in the range of 70° to 110°, and preferably 85° to 95°.

Exemplarily, the vapor phase deposition may use any existing technology familiar to those skilled in the art, preferably chemical vapor deposition (CVD), such as low temperature chemical vapor deposition (LTCVD), low pressure chemical vapor deposition (LPCVD), rapid thermal chemical vapor deposition (RTCVD), plasma enhanced chemical vapor deposition (PECVD).

Specifically, the process conditions for forming the epitaxial layer comprise: placing the wafer 100 in a processing chamber, and exposing the surface of the pre-processed wafer to a deposition gas to form an epitaxial layer on the surface of the wafer 100. The processing chamber is maintained in a temperature range of 1000° C. to 1200° C., preferably 1100° C. to 1150° C., and the pressure in the processing chamber is ambient pressure (ie, 760 Torr).

The deposition gas comprises a silicon source. The flow rate of the primary gas stream supplied from the silicon source to the processing chamber is 60 slm-120 slm, and the flow rate of the edge secondary flow 201 supplied by the silicon source to the processing chamber is 0-2900 sccm, preferably 1500 sccm-2000 sccm. Silicon sources that can be used in deposition gases to deposit silicon-containing compounds comprise: silanes, dichlorosilanes (DCS), and trichlorosilanes (TCS). As an example, the silicon source is trichlorosilane (TCS), and the epitaxial layer formed is a single crystal silicon layer.

The silicon source is provided into the processing chamber with a carrier gas. The flow rate of the primary gas stream supplied from the carrier gas to the processing chamber is 1 slm to 100 slm, preferably 50 slm to 80 slm, and the flow rate of the edge secondary gas stream 201 supplied from the carrier gas to the processing chamber is 500 sccm-2000 sccm, preferably 1000 sccm-1500 sccm. The carrier gas may comprise nitrogen (N₂), hydrogen (H₂), argon, helium, and combinations thereof. The carrier gas is usually selected based on the precursors and/or processing temperatures used in the deposition process. In this embodiment, the temperature of the processing chamber is greater than 1000° C. Therefore, hydrogen (H₂) is used as the carrier gas.

As shown in FIG. 3, the TCS flow at the edge secondary airflow 201 is tuned to determine whether the SFQR value can be reduced by tuning the TCS flow to improve the flatness of the wafer. Specifically, the curve \textcircled{1} of H₂ in FIG. 3 is 500 sccm and the flow rate of TCS is 0; the curve of \textcircled{2} H₂ in FIG. 3 is 500 sccm and the flow rate of TCS is 500 sccm; the flow of curve \textcircled{3} H₂ in FIG. 3 is 500 sccm and the flow rate of TCS is 1000 sccm; the flow of curve \textcircled{4} H₂ in FIG. 3 is 500 sccm, the flow of TCS is 2000 sccm; the flow of curve \textcircled{5} H₂ in FIG. 3 is 500 sccm, and the flow of TCS is 2900 sccm. Experiments have proved that it is not possible to improve the flatness of the wafer by just tuning the flow rates of TCS.

As shown in FIG. 2, the flow of H₂ at the edge secondary airflow 201 is tuned to determine whether the SFQR value can be reduced by tuning the flow rates of H₂ to improve the flatness of the wafer. Specifically, the curve \textcircled{1} of H₂ in FIG. 2 is 500 sccm and the flow rate of TCS is 1000 sccm; the curve of \textcircled{2} H₂ in FIG. 2 is 1000 sccm and the flow rate of TCS is 1000 sccm; and the curve of \textcircled{3} H₂ in FIG. 2 is 2000 sccm and the flow rate of TCS is 1000 sccm. Experiments have shown again that the flatness of the wafer cannot be improved by just tuning the flow rates of H₂.

The reactions that occur during the growth of the epitaxial layer include:

SiHCl₃+H₂↔SiH₂Cl₂+HCl (1)

SiHCl₃↔SiCl₂+HCl (2)

SiH₂Cl₂↔SiCl₂+H₂ (3)

SiCl₂+H₂↔Si+2HCl (4)

2SiCl₂↔Si+SiCl₄ (5)

Exemplarily, the gas that suppresses the growth of the epitaxial layer comprises HCl. When HCl is added, the concentration of HCl increases, which suppresses the forward reaction of the formula (2) and formula (4), thereby suppressing the the growth of Si makes the edge morphology of the epitaxial layer tend to be smooth.

As shown in FIG. 5, the flow rates of HCl at the edge secondary airflow 201 is tuned to determine whether the SFQR value can be reduced by tuning the flow rates of HCl to improve the flatness of the wafer. Specifically, the flow rate range of H₂ in FIG. 5 is 1000 sccm-1500 sccm, preferably 1200 sccm; the flow rate range of TCS is 1500 sccm-2000 sccm, preferably 1700 sccm; the curve \textcircled{1} the flow rate of HCl is 0 sccm; the curve \textcircled{2} the flow rate of HCl is 100 sccm; the curve \textcircled{3} the flow rate of HCl is 200 sccm; curve \textcircled{4} flow of HCl is 300 sccm; curve \textcircled{5} flow of HCl is 400 sccm; curve \textcircled{6} flow of HCl is 500 sccm. According to the experimental results in FIG. 5, the flow range of HCl is 0-1000 sccm, preferably 0-300 sccm, which suppresses the growth of edge Si, reduces the SFQR value, and improves the flatness of the wafer.

According to the present invention, a method for improving the flatness of a semiconductor thin film is provided by introducing a gas that suppresses the growth of the epitaxial layer when performing vapor deposition. In order to tune the thickness of the epitaxial layer located at the edge region of the wafer, the growth of the epitaxial layer is suppressed, the morphology at the edge is improved, and the access through vapor phase deposition is reduced. A gas that suppresses the growth of the epitaxial layer to tune the thickness of the epitaxial layer located at the edge region of the wafer, suppresses the growth of the edge epitaxial layer, improves the morphology at the edge, and reduces the SFQR value as well as improve the flatness of the epitaxial layer.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A method for improving flatness of a semiconductor thin film, comprising the steps of:
providing wafer; and
performing a vapor phase deposition process to grow an epitaxial layer on the wafer;
wherein a gas suppressing the growth of the epitaxial layer is employed during the vapor phase deposition process to tune the thickness of the epitaxial layer located at the edge region of the wafer and improve the flatness of the epitaxial layer.

2. The method according to claim 1, wherein the vapor phase deposition process comprises chemical vapor deposition process.

3. The method according to claim 1, wherein the vapor phase deposition process comprise a primary airflow and an edge secondary airflow.

4. The method according to claim 3, wherein the epitaxial layer comprises a central region and an edge region, the primary airflow is set to control the thickness of the epitaxial layer in the center region of the wafer, and the edge secondary airflow is set to control the thickness of the epitaxial layer at the edge region of the wafer.

5. The method according to claim 4, wherein the edge secondary airflow comprises at least a gas suppressing the growth of the epitaxial layer.

6. The method according to claim 1, wherein the gas suppressing the growth of the epitaxial layer comprises HCl.

7. The method according to claim 6, wherein the vapor phase deposition process further comprises a deposition gas, the deposition gas comprises trichlorosilane; and the vapor phase deposition process further comprises a carrier gas, the carrier gas comprises H₂.

8. The method according to claim 7, wherein the trichlorosilane flow rate is in a range of 1500˜2000 sccm, the H₂ flow rate is in a range of 1000˜1500 sccm, and the HCl flow rate is in a range of 0˜300 sccm.

9. The method according to claim 1, wherein the epitaxial layer comprises single crystal silicon.

10. The method according to claim 3, wherein an angle between the direction of the primary airflow and the direction of the edge secondary airflow is 70°-110°.
